(19) United States
(12) Patent Application Publication
(10) Pub. No.: US 2021/0020448 A1
(43) Pub. Date: Jan. 21, 2021

(54) Method and Structure for Smoothing Substrate Patterns or Surfaces

(71) Applicant: Tokyo Electron Limited, Tokyo (JP)

(72) Inventors: Qiaowei Lou, Albany, NY (US); Angelique Raley, Albany, NY (US); Alok Ranjan, Austin, TX (US)

(21) Appl. No.: 16/513,602

(22) Filed: Jul. 16, 2019

(51) Int. Cl. H01L 21/3105; H01L 21/311; H01L 21/02

(52) U.S. Cl. CPC H01L 21/31051; H01L 21/31144; H01L 21/31111; H01L 21/02164; H01L 21/31116; H01L 21/0228

(57) ABSTRACT

Described herein is an innovative method smoothing substrate surfaces. The surfaces to be smoothed may be a surface of a patterned feature of the substrate or may be an unpatterned surface of the substrate. The techniques disclosed utilize atomic layer deposition (ALD) techniques to smooth surfaces. For example, the use of ALD to smooth the line edge roughness of a patterned feature or roughness of a surface of an unpatterned layer is described. ALD can grow high quality films with atomic level thickness controllability and conformality. The rough, sharp asperities on patterned features (for example on sidewalls or tops of a patterned feature) or on a surface can be smoothed by precisely growing material layer by layer over the rough surface. Thus, asperities on a surface may be smoothed, improving the manufacturability and/or device performance.

### BACKGROUND

The present disclosure relates to the processing of substrates. In particular, it provides a novel method for smoothing rough surfaces or patterns. In one embodiment, the substrate may be a semiconductor substrate.

As geometries in substrate processing continue to shrink, the technical challenges to forming structures on substrates increase. It has been found that as pitches and dimensions decrease, the line edge roughness (LER) of pattern features degrades during the pattern transfer process. LER has become particularly problematic limitation when minimum feature sizes shrink to the tens of nanometers and less. LER can be problematic to both device formation and device operating characteristics. Similarly, non-patterned surfaces may exhibit roughness and this roughness may also be problematic for device formation and operating characteristics. Thus, whether the surface is a surface of a patterned feature (such as a feature formed on a substrate, for example, by lithography patterning and etch techniques) or the surface is an unpatterned surface, surface roughness has become more problematic in substrate processing.

It would be desirable to provide a process technique that reduces surface roughness.

### SUMMARY

Described herein is an innovative method smoothing substrate surfaces. The surfaces to be smoothed may be a surface of a patterned feature of the substrate or may be an unpatterned surface of the substrate. The techniques disclosed utilize atomic layer deposition (ALD) techniques to smooth surfaces. For example, the use of ALD to smooth the line edge roughness of a patterned feature or roughness of a surface of an unpatterned layer is described. ALD can grow high quality films with atomic level thickness controllability and conformality. The rough, sharp asperities on patterned features (for example on sidewalls or tops of a patterned feature) or on a surface can be smoothed by precisely growing material layer by layer over the rough surface. Thus, asperities on a surface may be smoothed, improving the manufacturability and/or device performance.

More specifically, described herein is a method of smoothing a line edge roughness on etched layers. The etched layers may be patterned features to be formed on a substrate. The etched layers may also be hard mask features or other masking features utilized when patterning substrates. In one embodiment, a layer is etched resulting in a patterned feature which exhibits a degree of line edge roughness. The amount of line edge roughness on the patterned feature is reduced by forming successive ALD layers on the line edge so as to reduce the line edge roughness.

In one embodiment, a method for processing a substrate is provided. The method comprises providing a masking layer and providing the substrate with a first layer. The method further comprises etching the first layer according to a pattern of the masking layer to form an etched layer, the etched layer having at least a first surface, the first surface having a first surface roughness. The method additionally comprises utilizing an atomic layer deposition process to form a plurality of atomic level additional layers over the first surface of the etched layer, wherein a final atomic level additional layer of the plurality of atomic level additional layers has a second surface roughness, the second surface roughness being less than the first surface roughness.

In another embodiment, a method for processing a substrate is provided. The method comprises etching a first layer to form an etched layer, the etched layer having a plurality of sidewalls, the sidewalls having a first surface roughness. The method further comprises utilizing an atomic layer deposition process to form a plurality of atomic level additional layers over the sidewalls of the etched layer, the plurality of atomic level additional layers being at least five additional layers, wherein a final atomic level additional layer of the plurality of atomic level additional layers has a second surface roughness, the second surface roughness being less than the first surface roughness.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 illustrates a feature having a surface, where the surface exhibits a surface roughness.

FIG. 2 illustrates the formation of a plurality of atomic level ALD layers formed over the surface of FIG. 1.

FIG. 3 illustrates a comparison of the roughness of the outer surface of the feature of FIG. 1 and the outer surface of the feature of FIG. 2.

FIG. 4A illustrates an etched layer having a sidewall surface roughness.

FIG. 4B illustrates the etched layer of FIG. 4B after the formation of a plurality of ALD layers as described herein to provide a smoother etched layer surface.

FIGS. 5-6 illustrate exemplary methods utilizing the smoothing techniques described herein.

### DETAILED DESCRIPTION

Described herein is an innovative method smoothing substrate surfaces. The surfaces to be smoothed may be a surface of a patterned feature of the substrate or may be an unpatterned surface of the substrate. The techniques disclosed utilize atomic layer deposition (ALD) techniques to smooth surfaces. For example, the use of ALD to smooth the line edge roughness of a patterned feature or roughness of a surface of an unpatterned layer is described. ALD can grow high quality films with atomic level thickness controllability and conformality. The rough, sharp asperities on patterned features (for example on sidewalls or tops of a patterned feature) or on a surface can be smoothed by precisely growing material layer by layer over the rough surface. Thus, asperities on a surface may be smoothed, improving the manufacturability and/or device performance.

More specifically, described herein is a method of smoothing a line edge roughness on etched layers. The etched layers may be patterned features to be formed on a substrate. The etched layers may also be hard mask features or other masking features utilized when patterning substrates. In one embodiment, a layer is etched resulting in a patterned feature which exhibits a degree of line edge roughness. The amount of line edge roughness on the patterned feature is reduced by forming successive ALD layers on the line edge so as to reduce the line edge roughness.

In one embodiment, a rough surface may be provided as part of a substrate. As mentioned, the rough surface may be, for example, a surface of a patterned feature. According to the techniques described herein, an ALD layer may be formed on the rough surface in order to provide a smoother surface. More particularly, atom by atom formation of multiple ALD layers may incrementally smooth the rough surface to yield a final surface which is smoother than the original rough surface.

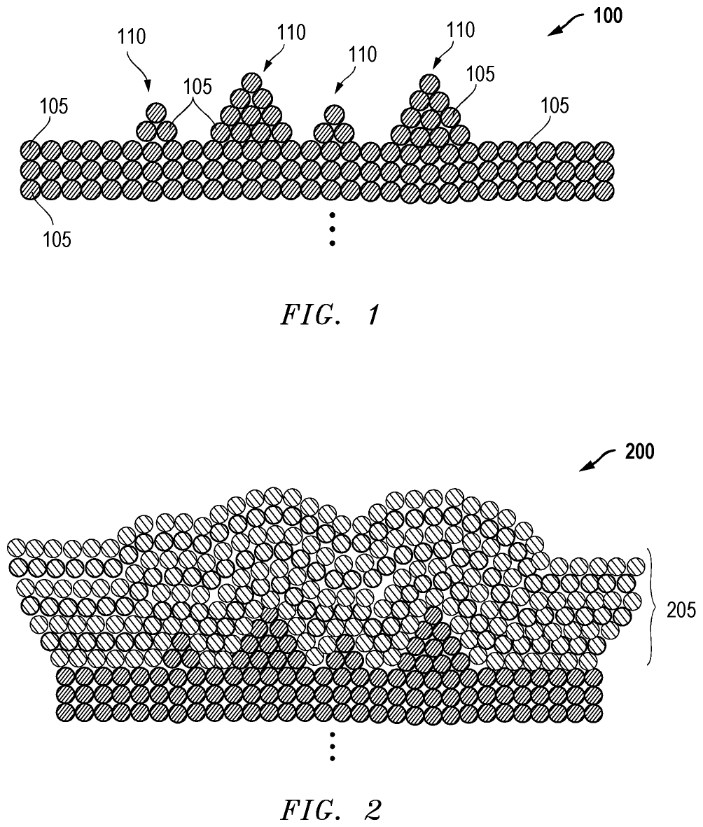

For example, FIG. 1 illustrates the outermost layers of a feature 100 that shows a rough surface. As shown, the circles correspond to atoms 105 of the material which forms the feature 100. As shown, the feature 100 may include asperities 110. It will be recognized that the atoms 105 shown are just the outermost portions of the surface of the feature 100. The surface may be the surface of a unpatterned layer of material (for example the top layers of atoms of an unpatterned surface) or the surface may be a sidewall or top of a patterned feature (in the case of the sidewall, the surface may be viewed as being turned vertically from the horizontal orientation of FIG. 1 which is used for demonstrative purposes).

The feature 100 of FIG. 1 may then be subjected to an atomic layer deposition process. By utilizing atomic layer deposition, successive layers of additional atoms may be formed over the rough surface. For example, as shown in FIG. 2, seven additional atomic layers 205 may be added to the rough surface to form a feature 200. Thus, a plurality of atomic level additional layers may be provided over the rough surface of feature 100. As shown in FIG. 2, each additional layer successively provides a smoother surface so as to minimize the sharp, rough features of the original layer. In this manner, the merging of deposition front from ALD can lead to smoothing of surface asperities.

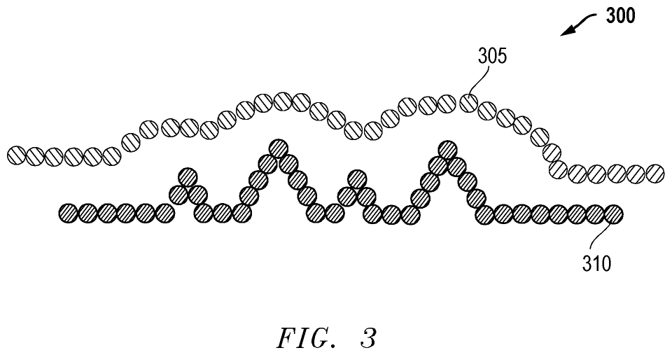

To ease the comparison of the original surface and the final surface, FIG. 3 illustrates a feature 300 which just illustrates the outermost portion 305 of the additional atomic layers 205 and the original outermost portion 310 of the atoms of the original surface of the feature 200 of FIG. 2. As seen in FIG. 3, substantial smoother surface is achieved through the use of the ALD formation process.

As illustrated, it will be recognized that varying levels of smoothness may be obtained by the number of atomic layers formed on the original surface. In the example shown, more than 5 atomic layers are provided, and in particular seven atomic layers are provided, although more or less layers may be desirable depending upon the amount of smoothing desired and other process variables. In one embodiment, the number of additional layers is twenty or less atomic layers. In another embodiment the number of additional layers is ten or less atomic layers.

The techniques described herein may be utilized to smooth surfaces that have roughness caused by any of a variety of reasons. For example, the roughness may be line edge roughness that results from processing very narrow linewidth and pitch structures. The roughness may also result from roughness that occurs when patterns are transferred (for example via etch) from one layer to another such as when using hard mask or lithography masks. In addition, the roughness may merely be the roughness that results from a layer formation step (such as a growth or deposition step) or even the natural crystalline nature and/or grain boundaries of a given layer.

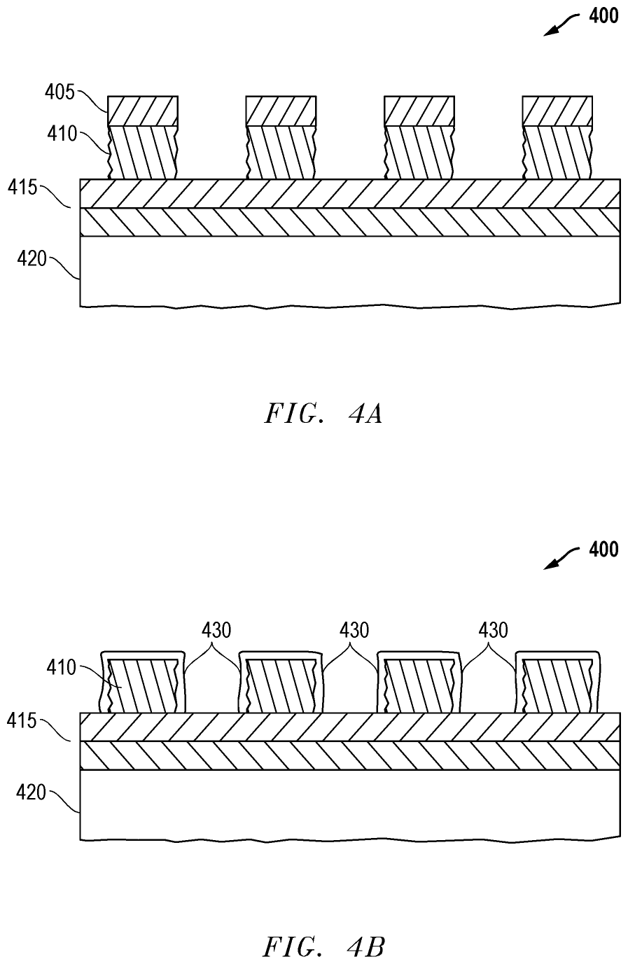

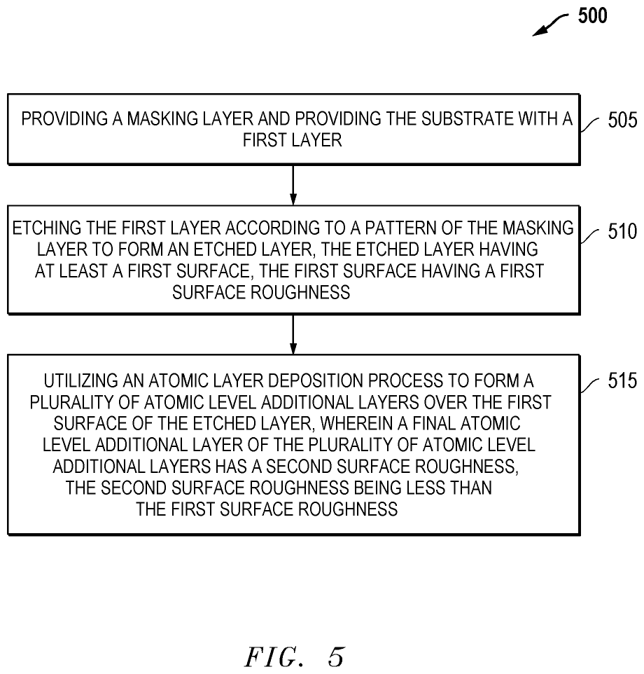

The techniques described herein are beneficial for addressing line edge roughness of a wide range of pitch structures, from several micrometers to tens of nanometers, especially for narrow pitch structures. FIG. 4A illustrates a structure 400 to which the techniques described herein may be applied. It will be recognized that the pattern of structure 400 is merely exemplary. Structure 400 may be a structure which has small critical dimensions, for example pitches of 30 nm or less. As shown, structure 400 includes a masking layer 405 overlying an etched layer 410. Masking layer 405 may be any masking layer known in the art. For example, masking layer 405 may be a photo resist layer, hard mask layer or other masking layer. Etched layer 410 may be any type of layer that is desired to be etched. The etch process utilized may be any of a wide variety of etch processes known in substrate processing, including dry or wet etch techniques. Etched layer 410 may, in some examples, be further used as a mask for etching additional layers 415 which may underlie etched layer 410. The structure 400 may all overly a substrate 420 that may include any number of additional layers and features (patterned and unpatterned).

As shown in FIG. 4A, the etched layer 410 may exhibit line edge roughness. Such line edge roughness may exhibit surface asperities characteristics such as shown in FIG. 1. In one example, the line edge roughness may result from the etch process used to etch the etched layer 410.

Next, an atomic layer deposition process may be utilized to smooth the line edge roughness of etched layer 410. The atomic layer deposition process may be performed before removal of the masking layer 405 or may be performed after the masking layer 405 has been removed. As shown in FIG. 4B, an exemplary embodiment is shown in which the masking layer 405 has been removed and then multiple atomic layers of an atomic layer deposition process have been formed. As shown in FIG. 4B, atomic deposition layer 430 is provided over the etched layer 410 of the structure 400. The atomic deposition layer 430 may be comprised over a plurality of atomic level layers such as shown in FIG. 2, which together successively smooth the rough surfaces of the etched layer 410 such as shown in FIG. 4B. In this manner, an atomic layer deposition process is used to smooth the rough edges of a narrow pitch etched layer by providing multiple atomic level layers.

The particular material used for the additional atomic layers may be the same as the underlying rough surface of the etched layer or may be a different material. Factors that may impact the choice of additional atomic layer material may include the ability to form a particular material controllably and conformally. Another factor to consider may be the adhesion characteristics of the additional material to the material that forms the rough surface. In one example, a rough silicon oxide surface may be smoothed by the formation of additional silicon oxide ALD layers. In such an example, the ALD processes for forming silicon oxide are well known in the art, and are known to be controllable. Further, the formation of silicon oxide ALD layers on an underlying silicon oxide layer provides desirable adhesion characteristics. It will be recognized that the use of silicon oxide for the underlying and/or ALD layers is merely exemplary. The underlying rough layer and the ALD layers may be comprised of any of a wide variety of materials known in the substrate processing art, including but not limited to conductive materials, dielectric materials, and other materials.

In one embodiment, the etched layer 410 may be a silicon oxide layer used for hard mask open. The etched layer may exhibit line edge roughness in the range of 3˜4 nm. The silicon oxide features may have line widths of 15 to 40 nm and spaces of 15 to 40 nm. An ALD process may be used to deposit atomic layers of silicon oxide. Any of wide variety of ALD processes may be utilized. In one example, the ALD process is a cyclic process of exposure of the substrate to Tris(dimethylamino)silane (3DMAS) and oxygen (O2) as Si precursor and oxygen source, respectively. In one exemplary embodiment, approximately 10 atomic layers may be formed, providing approximately a 2 nm thick layer over the silicon oxide etched layer. In one exemplary embodiment, the line roughness may be reduced by 20%. In this manner the use of an ALD process to reduce the line edge roughness of a narrow pitch structure may be advantageously utilized.

As disclosed above, the ALD process provides a smoother surface as compared to the original rough surface. However, the techniques described herein may be combined with an additional layer removal process. For example, after achieving the smoother surface of FIG. 2 or 4B, the substrate may be subjected to an etch back step. The etch back may be a dry etch (for example a plasma etch) or a wet etch or a combination of dry and wet etching. The etching may consume some or all of the additional layers that were formed by the ALD process. After etching, the etched back surface of the final structure will still however exhibit the generally smoother nature of the upper most ALD layer. Thus, an etched back surface roughness is less rough than the original surface roughness before the addition of the atomic level additional layers. In one embodiment, the ALD process and the etch back process may be performed in-situ in the same process tool. For example, the ALD process may be incorporated with a standard plasma etch process such that the ALD layer formation may be, if desired, formed in-situ in the same plasma process tool as the etch back process is performed.

In yet another embodiment, the smoothing process may consist of a cyclic process of a series one or more ALD formation steps, followed by etch back, followed by more ALD formation, followed by etch back, etc. In one embodiment, the cyclic series of ALD and etch steps are cyclically performed in-situ in one process tool.

One exemplary reason to consider the use of an etch back is that the use of the ALD process which provides additional atomic layers may add to the total thickness of a substrate layer and/or the change the dimensions of the various features on the substrate (for example sidewall deposition may increase the linewidth of a line or decrease the size of a via). The etch back process may maintain the smoothness of the surface that was achieved by ALD formation, yet trim the thickness and/or feature dimensions back to a desired size.

The techniques disclosed herein may be utilized during the processing of a wide range of substrates. The substrate may be any substrate for which the use of smooth surfaces (for example surfaces of patterned features or surfaces of unpatterned layers) is desirable. For example, in one embodiment, the substrate may be a semiconductor substrate having one or more semiconductor processing layers (all of which together may comprise the substrate) formed thereon. Thus, in one embodiment, the substrate may be a semiconductor substrate that has been subject to multiple semiconductor processing steps which yield a wide variety of structures and layers, all of which are known in the substrate processing art, and which may be considered to be part of the substrate. For example, in one embodiment, the substrate may be a semiconductor wafer having one or more semiconductor processing layers formed thereon. The concepts disclosed herein may be utilized at any stage of the substrate process flow, for example front end of line (FEOL) processing steps and back end of line (BEOL) processing steps.

As mentioned, the particular material used for the additional ALD layers may be any of a wide range of materials. Further, as is known in the art, a wide range of formation processes may be utilized in ALD processes for any particular material which is being formed. Thus, the techniques disclosed herein are not limited to a particular ALD process. ALD processes are well known in the art and typically involve the formation of very thin layers of material on a surface. As known, exemplary ALD processes (though not all) utilize one or more reactants which react with a surface in a self-limiting (or near self-limiting) way such that layer growth on the surface is limited by atomic monolayer surface saturation of attachment molecules. Typically, two or more reactants may be utilized in a sequential manner, such that the surface is exposed to one reactant for a self-limiting reaction, then a purge occurs, then exposure to another reactant for another self-limiting reaction occurs, and then another purge occurs. This cycle may be repeated until the desired material thickness is achieved. The ALD methodology provides for repeatable, atomic-level uniformity and conformality.

Thus, it will be recognized that a wide range of ALD processes may be utilized to form the ALD layers that are used as surface layers as described herein. Thus, the techniques described are not limited to a particular deposition process. In one exemplary embodiment, the ALD layers may be silicon oxide formed through the use of an ALD process that includes silicon (Si) precursor and oxygen (O) resource with a cyclical process of exposure of the substrate to a silicon precursor gas like silanes and then exposure to an oxidation gas like ozone (O3). Deposition is either non plasma based or plasma assisted (for example LTO-520 (an aminosilane chemical) or Tris(dimethylamino)silane (3DMAS) or other silicon-based precursor, alternating exposure with ozone or plasma SiO2, with both components prevented from mixing). In one embodiment, ALD is a process wherein conventional chemical vapor deposition (CVD) processes are divided into separate deposition steps to construct the thin film by sequentially depositing single atomic monolayers in each deposition step. The technique of ALD is often based on the principle of the formation of a saturated monolayer of reactive precursor molecules by chemisorption. A typical ALD process consists of injecting a first precursor for a period of time until a saturated monolayer is formed on the substrate. Then, the first precursor is purged from the chamber using an inert gas. This is followed by injecting a second precursor into the chamber, also for a period of time, thus forming a layer on the wafer from the reaction of the second precursor with the first precursor. Then, the second precursor is purged from the chamber. This process of introducing the first precursor, purging the process chamber, introducing the second precursor, and purging the process chamber is repeated a number of times to achieve a film of the desired number of atomic level layers. It will be recognized, however, that the techniques described herein may be utilized with alternative ALD processes and equipment. In addition, the description of a silicon oxide ALD process is merely exemplary. For example, in one exemplary embodiment, the ALD layers may be a silicon nitride formed through the use of an ALD process that includes an Si precursor and a nitrogen (N) resource with a cyclical process of exposure of the substrate to a silicon precursor gas like silanes and then exposure to an nitrogen-included gas like ammonia (NH3) with thermal or plasma activation. Deposition is either non plasma based or plasma assisted. Again, though, such a particular ALD process is merely exemplary, and it will be recognized that the ALD layers may be comprised of a wide range of materials.

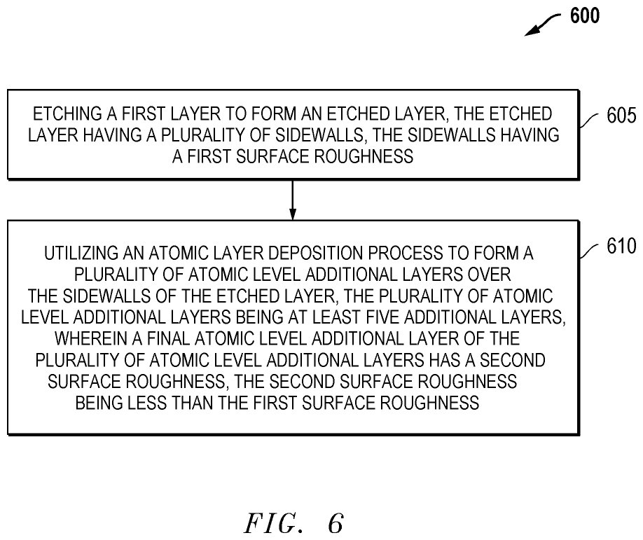

FIGS. 5-6 illustrate exemplary methods for use of the processing techniques described herein. It will be recognized that the embodiments of FIGS. 5-6 are merely exemplary and additional methods may utilize the techniques described herein. Further, additional processing steps may be added to the methods shown in the FIGS. 5-6 as the steps described are not intended to be exclusive. Moreover, the order of the steps is not limited to the order shown in the figures as different orders may occur and/or various steps may be performed in combination or at the same time.

FIG. 5 illustrates an exemplary method 500 for processing a substrate. The method comprises step 505 of providing a masking layer and providing the substrate with a first layer. The method further comprises step 510 of etching the first layer according to a pattern of the masking layer to form an etched layer, the etched layer having at least a first surface, the first surface having a first surface roughness. The method additionally comprises step 515 of utilizing an atomic layer deposition process to form a plurality of atomic level additional layers over the first surface of the etched layer, wherein a final atomic level additional layer of the plurality of atomic level additional layers has a second surface roughness, the second surface roughness being less than the first surface roughness.

FIG. 6 illustrates another exemplary method 600 of processing a substrate. The method comprises step 605 of etching a first layer to form an etched layer, the etched layer having a plurality of sidewalls, the sidewalls having a first surface roughness. The method further comprises step 610 of utilizing an atomic layer deposition process to form a plurality of atomic level additional layers over the sidewalls of the etched layer, the plurality of atomic level additional layers being at least five additional layers, wherein a final atomic level additional layer of the plurality of atomic level additional layers has a second surface roughness, the second surface roughness being less than the first surface roughness.

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as presently preferred embodiments. Equivalent techniques may be substituted for those illustrated and described herein and certain features of the inventions may be utilized independently of the use of other features, all as would be apparent to one skilled in the art after having the benefit of this description of the inventions.

1. A method for processing a substrate, comprising:
providing a masking layer;
providing the substrate with a first layer;
etching the first layer according to a pattern of the masking layer to form an etched layer, the etched layer having at least a first surface, the first surface having a first surface roughness; and
utilizing an atomic layer deposition process to form a plurality of atomic level additional layers over the first surface of the etched layer,
wherein a final atomic level additional layer of the plurality of atomic level additional layers has a second surface roughness, the second surface roughness being less than the first surface roughness.

2. The method of claim 1, wherein the first layer and the plurality of atomic level additional layers are comprised of a same material.

3. (canceled)

4. The method of claim 1, wherein the plurality of atomic level additional layers is twenty or fewer atomic level additional layers.

5. The method of claim 1, wherein the plurality of atomic level additional layers is ten or fewer atomic level additional layers.

6. The method of claim 1, wherein the plurality of atomic level additional layers is five or more atomic level additional layers.

7. (canceled)

8. The method of claim 9, wherein the first layer and the plurality of atomic level additional layers are comprised of silicon oxide.

9. The method of claim 1, further comprising:
an underlying layer is provided below the first layer;
prior to utilizing the atomic layer deposition process, removing the masking layer;
after forming the plurality of atomic level additional layers over the etched layer, etching back the atomic level additional layers to form an etched back surface, the etched back surface having an etched back surface roughness, the etched back surface roughness being less than the first surface roughness; and
after forming and etching back the plurality of atomic level additional layers the etched layer has a plurality of modified openings having sidewalls defined by the etched back surface of the atomic level additional layers which have been etched back, the method further comprising etching the underlying layer through the modified openings.

10. The method of claim 9, the etching back being performed with a dry etch.

11. The method of claim 10, the atomic layer deposition process and the etching back being performed in the same process tool.

12. The method of claim 9, the etching back being performed with a wet etch.

13. The method of claim 9, the atomic layer deposition process and the etching back being a cyclic process.

14. A method for processing a substrate, comprising:
etching a first layer to form an etched layer, the etched layer having a plurality of sidewalls, the sidewalls having a first surface roughness; and
utilizing an atomic layer deposition process to form a plurality of atomic level additional layers over the sidewalls of the etched layer, the plurality of atomic level additional layers being at least five additional layers, and after forming the plurality of atomic level additional layers over the etched lave etching back the atomic level additional layers to form an etched back surface, the etched back surface having an etched back surface roughness, the etched hack surface roughness being less than the first surface roughness,
wherein a final atomic level additional layer of the plurality of atomic level additional layers has a second surface roughness, the second surface roughness being less than the first surface roughness.

15. (canceled)

16. The method of claim 14, wherein the first layer and the plurality of atomic level additional layers are comprised of silicon oxide.

17. (canceled)

18. The method of claim 14, the atomic layer deposition process and the etching back being performed in the same process tool.

19. The method of claim 14, wherein the first layer and the plurality of atomic level additional layers are comprised of a same material.

20. The method of claim 14, the atomic layer deposition process and the etching back being a cyclic process.

21. A method of processing a substrate comprising:
providing a substrate including a mask layer, a first layer under the mask layer, and an underlying layer under the first layer, the first layer comprising silicon oxide;
etching the first layer through the mask layer to form an etched first layer having a plurality of openings;
removing the mask layer;
after removing the mask layer forming, by atomic layer deposition, a plurality of atomic level layers on sidewalls of the plurality of openings, the plurality of atomic level layers comprising silicon oxide;
etching back the plurality of atomic level layers so that the plurality of openings have the plurality of atomic level layers on sidewalls thereof which have been etched back; and
after the etching back, etching the underlying layer through the plurality of openings having the sidewalls on which the plurality of atomic level layers have been formed and etched back.
